(19) United States
(12) Patent Application Publication
(10) Pub. No.: US 2026/0187308 A1
(43) Pub. Date: Jul. 2, 2026

(54) Method for Quantitatively Evaluating Overall Damage of Building Structure based on Structural Strain Energy

(71) Applicant: GANSU URBAN AND RURAL PLANNING AND DESIGN RESEARCH INSTITUTE CO., LTD., Lanzhou, Gansu (CN)

(72) Inventors: Jia RUI, Lanzhou, Gansu (CN); Zhonghui LI, Lanzhou, Gansu (CN); Chunhao WANG, Lanzhou, Gansu (CN)

(73) Assignee: GANSU URBAN AND RURAL PLANNING AND DESIGN RESEARCH INSTITUTE CO., LTD., Lanzhou, Gansu (CN)

(21) Appl. No.: 18/863,541

(22) PCT Filed: May 13, 2024
(86) PCT No.: PCT/CN2024/092898

§ 371 Date: Nov. 6, 2024

(30) Foreign Application Priority Data
May 12, 2023 (CN) 202310535293.2

(51) Int. Cl. G06F 30/23

(52) U.S. Cl. CPC G06F 30/23

(57) ABSTRACT

The present disclosure provides a method for quantitatively evaluating overall damage of building structure based on structural strain energy, comprising: establishing an elastic-plastic calculation model, and preliminarily and secondarily screening seismic waves; applying seismic waves filtered at the second time to the elastic-plastic calculation model of the building structure for elasticity time history analysis, to acquire seismic waves; performing main shock and main aftershock bidirectional excitation on the elastic-plastic calculation model of the building structure by using the acquired seismic waves, and drawing an IDA curve; drawing basic calculation parameters, such as a graph of a family of IDA curves, percentile graphs, a building structure capacity curve and an energy versus time history graph under the action of the main shock and main after shock; calculating a structural strain energy-based building structure overall damage index by formulas, and performing quantitative evaluation on the building structure overall damage.

### TECHNICAL FIELD

The present disclosure relates to the technical field of overall structure damage assessment, and relates to a method for quantitatively evaluating overall damage of building structure based on structural strain energy.

### BACKGROUND

Under seismic action, the complexity and diversity of types of building structure systems and the uncertainty of ground motion both contribute to the complexity and diversity of types of earthquake damage and failure of the building structure systems. Therefore, establishing a damage model which is accurate and can reflect actual earthquake damage of a structure system is the key to engineering seismic resistance. Though the damage model, the degree of damage of the structure system can be quantitatively described, and the damage state of the structure system can be accurately determined, thereby guiding the adoption of suitable maintenance, reinforcement and improvement measures.

Actual earthquake disasters indicate that: earthquake damage and failure of a building structure system initiate at a material level, and accumulate and progress continuously, which causes member failure and then extends continuously to floor failure, and finally results in the failure of the whole function of the building structure system. Therefore, damage models for structure systems in the related art are mostly studied from three levels, i.e. a material level, a member level and a structure level. For earthquake damage at the material level, more research is made on the damage constitutive of the material, and how the material damage develops to the overall damage of the structure system requires more in-depth research. For earthquake damage at the member level, a member level damage model is proposed mostly according to experimental research on relevant beams and columns; and the structure overall damage is obtained by weighting and combining damage indexes of the members.

Hence, the evaluation of the overall damage of the building structure system is a process from microscopic to macroscopic. Due to the uncertainty of development paths of microscopic damage, it becomes very difficult to obtain a method for determining an overall damage model of a building structure system through basic formulas for determining damage at the material level and the member level.

In an initial stage of structural damage research, a single-parameter damage model is mainly configured to quantitative evaluation. However, as research delves deeper into the earthquake damage of structure systems, a single performance parameter cannot achieve comprehensive evaluation of the extent of damage of the structure system under the seismic action. Therefore, in order to overcome the limitation of the single-parameter damage model, a double-parameter failure criterion is used as a mechanism for evaluating the damage of the structure under a seismic action, and has been widely recognized in the engineering industry. In the double-parameter failure criterion, it is considered that: under the seismic action, damage to a building structure system is the result of joint effect of first-excursion failure and cumulative damage and failure; in which the first-excursion failure represents that a mechanical indicator of a maximum earthquake response (such as deformation and displacement, etc.) of the structure system firstly exceeds a specified limit value, thereby causing abrupt failure of the structure system; and the cumulative damage and failure is caused by different degrees of damage generated inside the structure system under the effect of reciprocal seismic action, resulting in degradation of the mechanical performance of the structure (such as strength and stiffness, etc.), which then causes continuous reduction of the bearing capacity of the structure system, and causes failure due to continuous accumulation of damage. Compared with a damage model at the member level, the structure overall damage index cannot be obtained due to the complexity of the structure itself and the lack of relevant experimental verification and the lack of complete theoretical derivation process; therefore, currently, there is no commonly recognized overall damage model.

### SUMMARY

An object of some embodiments of the present disclosure is to provide a method for quantitatively evaluating overall damage of building structure based on structural strain energy, which is configured to quantitatively evaluate the overall damage of building structure.

A solution adopted in some embodiments of the present disclosure is: a method for quantitatively evaluating overall damage of building structure based on structural strain energy, which is performed according to the following steps:
step 1) selecting geometric parameters, member sizes, material information, seismic motion parameters and material consecutive of the building structure, and establishing an elastic-plastic calculation model of the building structure by using finite element analysis software Abaqus;
step 2) based on the principles of selecting seismic records in “Code for Seismic Design of Buildings” GB50011-2010 and “Technical Specification for Concrete Structures of Tall Building” (JGJ3-2010), screening seismic waves preliminarily based on designed seismic intensity, site category and seismic grouping of the building structure;
designing a normative spectrum of the building structure based on the “Code for Seismic Design of Buildings” GB50011-2010 and “Technical Specification for Concrete Structures of Tall Building” JGJ3-2010, and secondarily screening the seismic waves by taking, as a principle, the difference between spectrum values of an average response spectrum of a seismic motion response spectrum corresponding to principal mode period points of the building structure and spectrum values of the specification spectrum being not greater than 20%;
applying seismic waves filtered at the second time to the elastic-plastic calculation model of the building structure for elasticity time history analysis, and final seismic motion screening is performed by taking, as a principle, a base shear force of the structure obtained by each seismic motion elasticity time history calculation being not less than 65% of a modal decomposition response spectrum method and an average value of the base shear force of the structure obtained by a plurality of seismic motion elasticity time history calculations being not less than 80% of the modal decomposition response spectrum method;
based on a final seismic motion screening principle, main shock seismic motion records are selected to obtain selected seismic waves;
step 3) performing main shock and main aftershock bidirectional excitation on the elastic-plastic calculation model of the building structure by using the selected seismic waves;
step 4) drawing an Incremental Dynamic Analysis (IDA) curve by taking a peak ground acceleration in the elastic-plastic calculation model subjected to bidirectional excitation as a seismic motion intensity measure, and selecting a maximum inter-story drift angle of a building structure system as a structural performance indicator;
step 5) performing non-uniform amplitude modulation on the seismic motion by using a Huntfill method, to search for collapse points of the building structure system is performed;
based on the Huntfill method, drawing a family of IDA curves of the building structure under the selected seismic motion action;
drawing the IDA curves as percentile curves of 16%, 50% and 84% by using an Intensity Measure (IM) criterion in a statistical manner;
taking a 50% percentile curve as a reference, for different building structure systems, taking a value of an ultimate inter-story drift angle of the 50% percentile curve as an ultimate inter-story drift angle of a damage model, wherein the ultimate inter-story drift angle is a curve point, where the slope of a connecting line between a certain point and a point preceding the certain point is less than 20%, on an IDA curve, and taking the curve point as a maximum displacement point of structural collapse;
with regard to the plurality of selected seismic waves, based on a data result of the multiple incremental dynamic analysis of IDA curves, a capacity curve of the building structure is drawn, and an average structural capacity curve is obtained, and calculating an area surrounded by the average structural capacity curve as an energy dissipation denominator E_{USE};
drawing an energy versus time history graph of the building structure under the action of the main shock and main after shock based on a seismic motion response time history of the structure, and a hysteretic energy dissipation E_{ΔE1} of a main shock and main after shock time history curve of the building structure is obtained, wherein the value of a strain energy increment E_{AEI} of the hysteretic energy dissipation is a ratio of the hysteretic energy dissipation E_{ΔE1} of the building structure to the seismic duration; and
6) based on a formula D_{SEN}=[(U_{rd}/U_{μd})^{1/2}]+ (E_{AEI}/E_{USE}), calculating building structure overall damage index based on structural strain energy, and performing quantitative evaluation on the building structure overall damage;
wherein D_{SEN} is the building structure overall damage index; U_{rd} is a maximum response inter-story drift angle of the building structure under a seismic action; U_{ud} is a maximum ultimate inter-story drift angle of the building structure; E_{AEI} is the strain energy increment of the hysteretic energy dissipation; and E_{USE} is an ultimate strain energy of the building structure under the seismic action.

Regarding the evaluation method in some embodiments of the present disclosure, said method learns from advantages and reasonable parts of existing methods for determining structure overall damage in the related art, and based on structural strain energy and through a coupling effect of first-excursion failure and cumulative damage and failure, a novel exponential model for quantitatively evaluating structure overall damage is obtained by derivation via a series of theoretical formulas; and then an operation process for a structural strain energy-based building structure overall damage exponential model is obtained by generalization and summarization, and by establishing the overall damage model, a structural strain energy-based structure overall damage index is proposed, and is used for quantitatively evaluating the degree of structure overall damage.

In some embodiments of the present disclosure, a strain energy indicator is selected to analyze a dynamic response of the structure under the seismic action, such that the damage degree of the structure can be reflected sensitively, and the one-sidedness of the damage model in the related art in evaluating the structure overall damage and failure mechanism through single displacement or a force concept-based failure criterion can also be better compensated. In addition, the method for quantitatively evaluating overall damage of building structure based on structural strain energy proposed in some embodiments of the present disclosure has a relatively complete theoretical research process; and by analysis and comparison between said method and a structure overall damage model in the related art, it has been found that the method for quantitatively evaluating overall damage of building structure based on structural strain energy in some embodiments of the present disclosure has certain reasonability and reliability in terms of evaluation of structure overall damage, and can also be well applied to super-high-rise building structures.

### BRIEF DESCRIPTION OF THE DRAWINGS

FIG. 1 is a flowchart of an evaluation method according to some embodiments of the present disclosure.

FIG. 2 is a graph of a family of IDA curves.

FIG. 3 is a percentile graph of IDA.

FIG. 4 is an IDA structural capacity curve and a strain energy graph.

FIG. 5 is a graph of strain energy versus time history of a building structure.

FIG. 6 is a relational diagram of first-excursion failure and cumulative hysteretic energy dissipation damage and failure.

FIG. 7 is a graph of structural ultimate strain energy.

### DETAILED DESCRIPTION OF THE EMBODIMENTS

Hereinafter, some embodiments of the present disclosure will be described in detail in conjunction with accompanying drawings and embodiments.

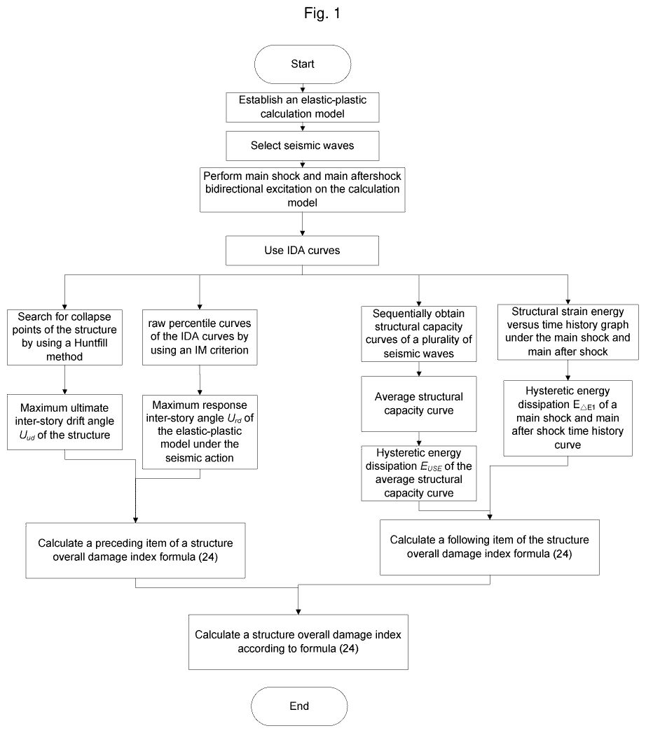

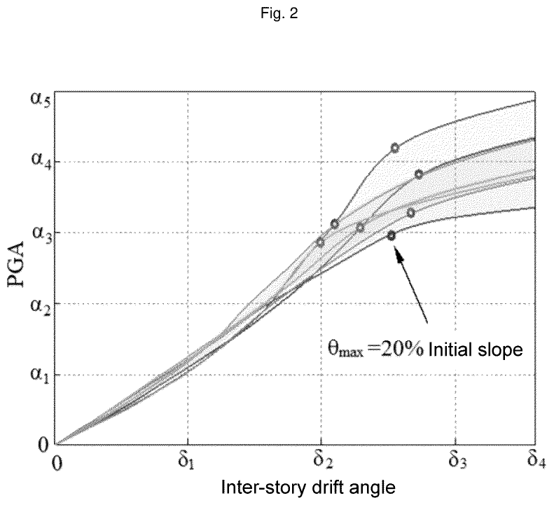

Some embodiments of the present disclosure provide a method for quantitatively evaluating overall damage of building structure based on structural strain energy, and the flow thereof is as shown in FIG. 1. The evaluation method is performed according to the following steps:
step 1) geometric parameters, member sizes, material information, seismic motion parameters and material consecutive of the building structure are selected, and finite element analysis software Abaqus is used to establish an elastic-plastic calculation model of the building structure, wherein geometric nonlinearity, material nonlinearity, and construction process nonlinearity are considered in an elastic-plastic analysis process;
step 2) based on principles of selecting seismic records in “Code for Seismic Design of Buildings” GB50011-2010 and “Technical Specification for Concrete Structures of Tall Building” (JGJ3-2010), seismic waves are preliminarily screened based on designed seismic intensity, site category and seismic grouping of the building structure;
a design response spectrum (normative spectrum) of the building structure is designed based on the “Code for Seismic Design of Buildings” GB50011-2010 and “Technical Specification for Concrete Structures of Tall Building” JGJ3-2010, and the seismic waves are secondarily screened by taking, as a principle, the difference between spectrum values of an average response spectrum of a seismic motion response spectrum corresponding to principal mode period points of the structure and spectrum values of the specification spectrum being not greater than 20%;
seismic waves filtered at the second time are applied to the elastic-plastic calculation model of the building structure for elasticity time history analysis, and final seismic motion screening is performed by taking, as a principle, the a base shear force of the structure obtained by each seismic motion elasticity time history calculation being not less than 65% of a modal decomposition response spectrum method and an average value of the base shear force of the structure obtained by a plurality of seismic motion elasticity time history calculations being not less than 80% of the modal decomposition response spectrum method; based on a final seismic motion screening principle, main shock seismic motion records are selected to obtain selected seismic waves;
step 3) the selected seismic waves are used to perform main shock and main aftershock bidirectional excitation on the elastic-plastic calculation model of the building structure, so as to simulate a bidirectional seismic effect, wherein amplitude modulation of a proportionality coefficient is performed on each selected seismic motion, such that the amplitude-modulated seismic motion records cover seismic motions to which the structure may be subjected in various stages from an elastic stage, an elastic-plastic stage to a collapse stage;
step 4) a peak ground acceleration (PGA) in the elastic-plastic calculation model subjected to bidirectional excitation is taken as a seismic motion intensity measure (IM), and a maximum inter-story drift angle (θₘₐₓ) of a building structure system is selected as a structural performance indicator (DM), to draw an Incremental Dynamic Analysis (IDA) curve;
a data processing principle for a plurality of IDA curves: assuming that each (Displacement-Intensity Measure) DM-IM curve is subject to logarithmic distribution, and under a DM value, an average value of different IM values and a standard deviation of different IM logarithmic values are obtained, and then three percentile curves can be obtained, i.e. IM criterion;
step 5) non-uniform amplitude modulation is performed on the seismic motion by using a Huntfill method, to search for collapse points of the building structure system is performed;
based on the Huntfill method, a family of IDA curves of the building structure under the selected seismic motion action as shown in FIG. 2 is drawn;
end points of the IDA curves which represent ultimate collapse points of the building structure is determined based on a structure collapse criterion. The Huntfill method, as a non-uniform seismic motion amplitude modulation method, can find structural collapse numerical points more accurately and rapidly based on the collapse criterion, such that the family of IDA curves plotted can reflect a change in the structural limit collapse performance more accurately.

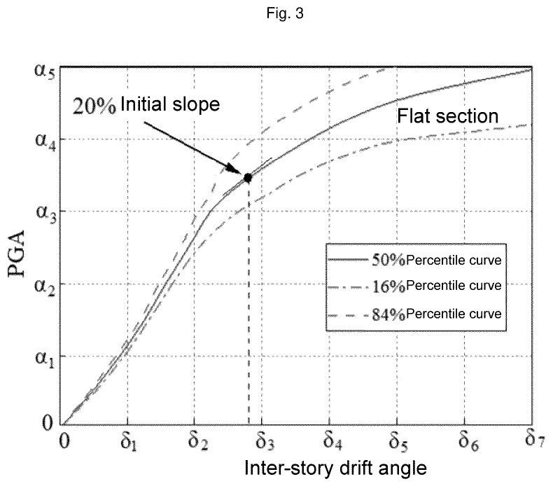

Based on an IDA rule, the IDA curves are drawn as percentile curves of 16%, 50% and 84% by using an Intensity Measure (IM) criterion in a statistical manner, as shown in FIG. 3. A 50% percentile curve is taked as a reference, for different building structure systems, a value of an ultimate inter-story drift angle of the 50% percentile curve is taken as an ultimate inter-story drift angle of a damage model, wherein the inter-story drift angle is a curve point, where the slope of a connecting line between a certain point and a point preceding the certain point is less than 20%, on an IDA curve, and the curve point is taken as a maximum displacement point of structural collapse, as shown in FIG. 2 and FIG. 3.

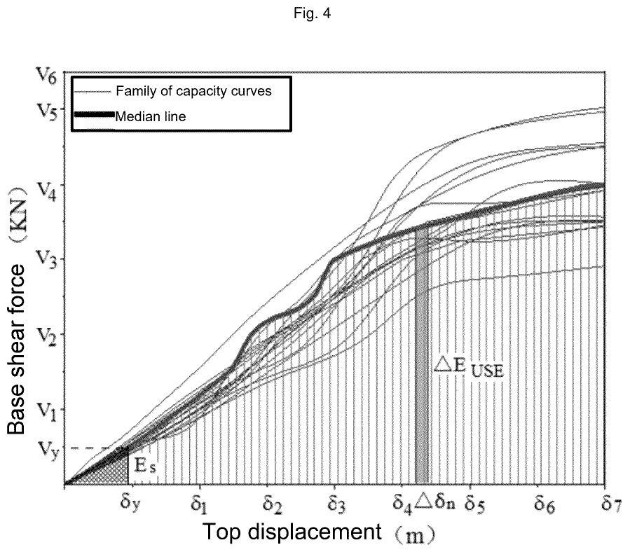

With regard to the plurality of selected seismic waves, based on a data result of multiple IDA curves, a capacity curve of the building structure is drawn, and an average structural capacity curve is obtained, and an area surrounded by the average structural capacity curve is calculated as an energy dissipation denominator E_{USE} of the damage model in the evaluation method of some embodiments of the present disclosure, as shown in FIG. 4.

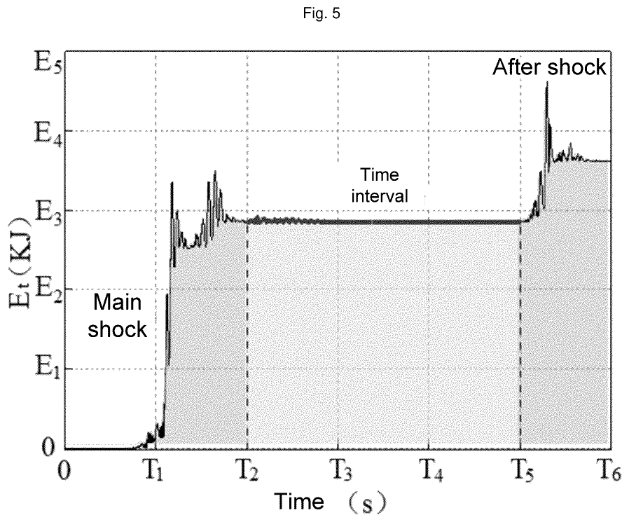

An energy versus time history graph of the building structure under the action of the main shock and main after shock as shown in FIG. 5 is drawn based on a seismic motion response time history of the structure, and when the energy dissipation capacity and seismic duration of the building structure system under the effects of the main shock and main after shock are obtained from FIG. 5, a hysteretic energy dissipation E_{ΔE1} of a main shock and main after shock time history curve of the building structure is obtained, wherein the value of a strain energy increment E_{AEI} of the hysteretic energy dissipation is a ratio of the hysteretic energy dissipation E_{ΔE1} of the building structure to the seismic duration;
step 6) based on a formula D_{SEN}=[(U_{rd}/U_{ud})^{1/2}]+(E_{AEI}/E_{USE}), a building structure overall damage index D_{SEN} is calculated, and quantitative evaluation is performed on the building structure overall damage.

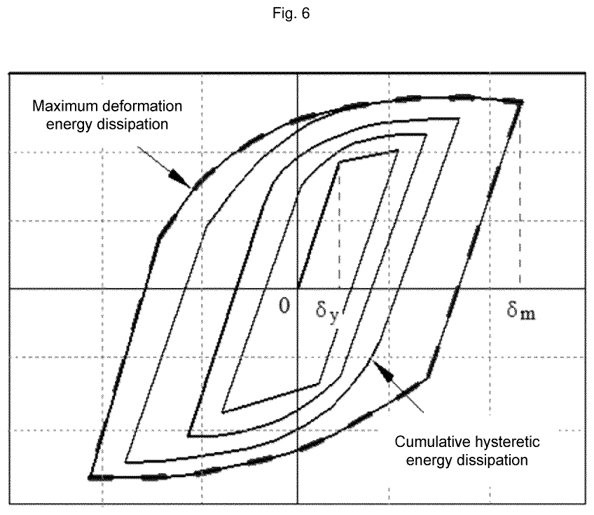

In the related art, a double-parameter failure criterion is used as a mechanism for evaluating the damage of a structure under a seismic action. In the double-parameter failure criterion, it is considered that: under the seismic action, damage to a building structure system is the result of joint effect of first-excursion failure and cumulative damage and failure, i.e. the mutual effect of limits of the maximum response and cumulative damage and failure of the building structure; and a relational diagram of the first-excursion failure and cumulative hysteretic energy dissipation damage and failure is as shown in FIG. 6. FIG. 6 shows that as the cumulative damage of the building structure increases, a control limit for the maximum response failure of the building structure decreases continuously; likewise, as the maximum response of the structure increases, the control limit for the cumulative damage and failure of the building structures also decreases continuously. Obviously, the double-parameter failure mechanism reflects that the failure of the building structure system under the seismic action is caused by joint effect of a large load magnitude and a repeated cyclic loading effect.

That is, the building structure overall damage index D_{SEN}=E_{RSE}/E_{USE} (1)

In the formula (1), E_{RSE} is response strain energy of the building structure system under the seismic action; and E_{USE} is ultimate strain energy of the building structure under the seismic action.

In addition, the response strain energy E_{RSE} of the building structure system under the seismic motion consists of two parts, i.e. the first-excursion failure and the cumulative damage and failure; therefore, the response strain energy E_{RSE} of the building structure system is:

$${E}_{RSE} = {E}_{FTBD} + {E}_{HEC} \qquad ( 2 )$$

by substituting formula (2) into formula (1), the building structure overall damage index is obtained:

$${D}_{SEN} = ( {E}_{FTBD} + {E}_{HEC} ) / {E}_{USE} = ( {E}_{FTBD} / {E}_{USE} ) + [ \int ( {E}_{HEC} , t ) / {E}_{USE} ] \qquad ( 3 )$$

wherein E_{FTBD} is a first-excursion failure response strain energy of the building structure system under the seismic action; E_{HEC} is a cumulative hysteretic energy dissipation response strain energy of the building structure system under the seismic action; ∫(E_{HEC},t) is a cumulative hysteretic energy dissipation function of the building structure system under the seismic action; and t is duration.

$$Generalized strain energy of a unit : Γ = \int \int {\int }_{v} kdv \qquad ( 4 )$$

$$k = {σ}_{ij} {ε}_{ij} / 2 \qquad ( 5 )$$

$${σ}_{ij} = {ε}_{ij} {C}_{ij} \qquad ( 6 )$$

wherein k is strain energy density; Cᵢⱼ is an elastic model matrix component; σᵢⱼ is unit stress; εᵢⱼ is unit strain; and vis volume of the unit.

By substituting formula (6) into formula (5), k=(ϑᵢⱼ²Cᵢⱼ)/2 (7) is obtained.

By substituting formula (7) into formula (4), a generalized strain energy Γ=∫∫∫ᵥεᵢⱼ²Cᵢⱼ dv (8) is obtained.

By differentiating formula (8), dΓ=Cᵢⱼ∫εᵢⱼdε∫∫∫ᵥdv (9) is obtained.

Throughout the damage time history of the building structure system, the elastoplastic behavior of the building structure system is basically assumed to be non-compressible, and therefore the change in the volume of structural members can be neglected. After a whole building structure is divided into units by using a finite element method, a generalized strain energy formula (9) of the whole structure can be rewritten as:

$$Γ = {\sum }_{1}^{n} {C}_{ij} \int {ε}_{ij} dε \qquad ( 10 )$$

By comparing formula (10) with Hooke's law, a generalized displacement of the building structure under the action of a load can be represented by U_{ω}, U_{ω}=Σεᵢⱼ; and generalized stiffness of the building structure is represented by K_{ω}, K_{ω}=ΣCᵢⱼ. Upon integration on formula (10), generalized strain energy Γ of the building structure is rewritten as Γ=(U_{ω}²K_{ω})/2 (11).

With regard to the generalized stiffness K_{ω} of the building structure, based on energy equivalence assumption proposed by Sidoroff, the generalized stiffness K_{ω} of the structure can also be expressed as:

$${K}_{ω} = {M}^{- 1} : C : {M}^{T , - 1} \qquad ( 12 )$$

In formula (12), M is a damage tensor of the building structure; C is an elastic tensor of a lossless structure; and ^{T} is a transpose of a matrix.

It can be determined from formula (12) that the generalized stiffness K_{ω} of the building structure is a nonlinear curve related to space coordinates and a loading path. Based on the second law of thermodynamics, under the seismic action, after a building structure system absorbs seismic energy, the building structure system is damaged, but the occurrence of damage sites of the building structure system exhibits randomness. With the development of the damage, the process of damage change of the building structure system will depend on the elastic tensor of a lossless structure, and is more represented as inherent physical attributes of the structure, and therefore it can be considered that any building structure system has a fixed generalized structural stiffness, that is, the generalized structural stiffness is a nonlinear curve. Thus, for different loading processes, the final plastic damage of the building structure system is manifested at different positions on a generalized stiffness curve of the structure.

The first-excursion failure refers to sudden failure of a structure system caused by a response mechanical indicator (such as: strength, displacement and ductility) of the structure first exceeding a limit value under a strong seismic action. The damage degree of the structure system under the seismic action has a direct relationship with the displacement of the structure system, and therefore formula (11) is substituted into the first item before the plus sign of formula (3), to obtain:

$${D}_{SE} = \frac{\frac{1}{2} {U}_{t}^{2} {K}_{ω}}{\frac{1}{2} {U}_{u}^{2} {K}_{ω}} + \frac{\int ( {E}_{HEC} , t )}{{E}_{USE}} \qquad ( 13 )$$

Formula (13) is organized to obtain:

$${D}_{SE} = \sqrt{\frac{{U}_{rd}}{{U}_{ud}}} + \frac{\int ( {E}_{HEC} , t )}{{E}_{USE}} \qquad ( 14 )$$

wherein Uᵣ is a maximum response displacement vector or the building structure under the seismic action; Uᵤ is an ultimate maximum displacement vector of the building structure; U_{rd} is a maximum response inter-story drift angle of the building structure under the seismic action; and U_{ud} is a maximum ultimate inter-story drift angle of the building structure.

The ultimate strain energy E_{USE} of the structure is ultimate strain energy dissipation capability of the structure. The Incremental Dynamic Analysis (IDA) used in the evaluation method of some embodiments of the present disclosure achieves more real reflection of nonlinear dynamic features of the structure system, and calculated feature values of the structural capacity curve can reflect structural energy dissipation and ultimate deformation capability more accurately, as shown in FIG. 4. The IDA method, due to the superiority in structural nonlinear stage evaluation, has been commonly applied as the most accurate calculation means up to now.

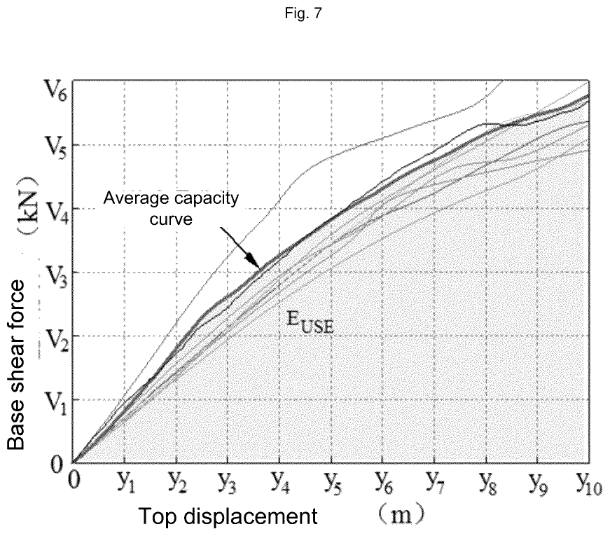

In the evaluation method of some embodiments of the present disclosure, a plurality of clusters of IDA curves of base shear force-top displacement are drawn by using a graphic method, the curves being as shown in FIG. 7. Based on strain energy formula (1), the area surrounded by an average value of the cluster of curves is taken as the ultimate strain energy E_{USE} of the structure system, i.e. formula (15),

$${E}_{USE} = {\int }_{{δ}_{y}}^{{δ}_{m}} Qdy \qquad ( 15 )$$

In formula (15), δₘ is a maximum deformation amount of the structure, δ_{y} is an ultimate elastic deformation amount of the structure, and Q is the base shear force.

The cumulative hysteretic energy dissipation damage and failure means that although dynamic response of the structure system cannot reach a failure limit of the first-excursion failure, the material properties (such as strength, stiffness and energy dissipation) of the structure are gradually deteriorated due to the cyclic seismic reciprocating action, which eventually causes collapse and failure of the structure system. Based on structural dynamics, the cumulative hysteretic energy dissipation function ∫_{(EHEC,t)} of the structure as a function of time in formula (14) can be expressed as formula (16), and the formula (16) can be converted into formula (17) in consideration of the accumulation over time,

$$\int ( {E}_{HEC} , t ) = {\int }_{0}^{u} fs ( u ) du - {E}_{S} ( t ) \qquad ( 16 )$$

$$\int ( {E}_{HEC} , t ) = [ {\int }_{0}^{t} \dot{u} fs ( u ) dt ] - {E}_{S} ( t ) \qquad ( 17 )$$

wherein E_{S}(t) is elastic strain energy of the structure over time; fₛ(u) is resistance force, u is a structural lateral displacement, and tis the duration.

As can be determined from the content above, the cumulative hysteretic energy dissipation ∫_{(EHEC,t)} is a function of time, and therefore it is necessary to discuss the relationship between the cumulative hysteretic energy dissipation and a variable, i.e. time.

Based on relevant documents, maximum plastic deformation energy dissipation of the structure system is defined as formula (15), then a maximum ductility coefficient u of the structure system can be expressed as: μ=(δₘ−δ_{y})/δ_{y} (18).

Under the seismic action, maximum ductility coefficients of the structure under the action of a positive load and a negative load are

$${μ}_{m}^{+} and {μ}_{m}^{-} ,$$

respectively; and ductility coefficients of ith loading within ranges of positive loading and negative loading are defined as η+ and η−, respectively:

$${η}^{+} = \frac{{E}_{p}^{+}}{{Q}_{y}^{+} {δ}_{y}^{+}} {η}^{-} = \frac{{E}_{p}^{-}}{{Q}_{y}^{-} {δ}_{y}^{-}} \qquad ( 19 )$$

In formula (19),

$${E}_{p}^{+}$$

is the hysteretic energy dissipation within the ith positive loading range, and

$${E}_{p}^{-}$$

is the hysteretic energy dissipation within the ith negative loading range; and due to symmetrical positive and negative loading, then:

$${Q}_{y}^{+} {δ}_{y}^{+} = {Q}_{y}^{-} {δ}_{y}^{-} = {Q}_{y} {δ}_{y} \qquad ( 20 )$$

An average value of the sum of η+ and η− is taken as an average cumulative ductility coefficient η̅, thereby obtaining:

$$\overline{η} = \frac{{E}_{p}^{+} + {E}_{p}^{-}}{2 \cdot {Q}_{y} {δ}_{y}} \qquad ( 21 )$$

By combining formula (19), formula (20) and formula (21), a total hysteretic energy dissipation formula is obtained:

$$\int ( {E}_{HEC} , t ) = 2 \cdot \overline{η} {Q}_{y} {δ}_{y} \qquad ( 22 )$$

In formula (22), Q_{y} is structure yield force, and δ_{y} is structure yield strain.

As can be determined from formula (22), the cumulative hysteretic energy dissipation of the structure system can be independent of the time variable, and the time variable is a duration increment in formula (17) and represents an increase with time. Thus, an incremental average value over time of the cumulative hysteretic energy dissipation function ∫_{(EHEC,t)} can be expressed as:

$${E}_{ARI} = \int ( {E}_{HEC} , t ) = \frac{\int {E}_{HEC} dt}{t} \qquad ( 23 )$$

In formula (23), E_{ARI} is hysteretic energy dissipation strain energy increment, and tis the period.

By substituting formula (14), formula (15) and formula (23) into formula (1), the structural strain energy-based building structure overall damage index D_{SEN} is finally obtained:

$${D}_{SEN} = [ {( {U}_{rd} / {U}_{μ d} )}^{1 / 2} ] + ( {E}_{AEI} / {E}_{USE} ) \qquad ( 24 )$$

In formula (24), E_{AEI} is a hysteretic energy dissipation average strain energy increment; E_{USE} is the ultimate strain energy of the structure; D_{SEN} is the building structure overall damage index (D_{SEN} in formula (1) is a definition formula, and after a series of derivations, formula (24) is obtained for evaluating the structure overall damage, and the calculation result is within a range of [0, 1]; when the building structure overall damage index is 0, it indicates that the entire building structure has no damage; and when the building structure overall damage index is 1, it indicates that the damage of the building structure is the greatest; and the larger the damage index, the larger the damage degree of the building structure.

Energy is an inherent physical attribute of interaction between an external environment and the structure system. The seismic response of the building structure system can be understood as a nonlinear process changing from static to dynamic based on time; and from the viewpoint of energy, the dynamic response of the building structure system can be understood as a process of transfer and release of structural strain energy, and the strain energy plays a dominant role in the whole process. The building structure overall damage is formed by the accumulation of plastic deformation of members, such that the structural strain energy has a good advantage in characterization of the accumulation of plastic deformation of the members of the structure; and the strain energy can better compensate for the one-sidedness of evaluating the structure overall damage and failure mechanism through single displacement or a force concept-based failure criterion. In addition, the structural strain energy can reflect the expansion of a plastic part of a structural member and the increase of the degree of plastic deformation. When the structural strain energy changes, it indicates that the structure is damaged, and the strain energy indicator is sensitive to structural damage. Analyzing the response condition of the structure system under the seismic action from the energy perspective can not only accurately reflect seismic intensity, duration, spectrum signature, etc. of the structure system when undergoing an earthquake, but also can reflect the whole process from seismic energy absorption to dissipation of the structure system. Therefore, the structural strain energy is configured to describe the damage extent of the whole structure when encountering a seismic action, and can reflect the actual earthquake damage condition of the whole structure.

What is claimed is:

1. A method for quantitatively evaluating overall damage of building structure based on structural strain energy, wherein the evaluation method is performed according to the following steps:
step 1) selecting geometric parameters, member sizes, material information, seismic motion parameters and material consecutive of the building structure, and establishing an elastic-plastic calculation model of the building structure by using finite element analysis software Abaqus;
step 2) based on principles of selecting seismic records in “Code for Seismic Design of Buildings” GB50011-2010, “Technical Specification for Concrete Structures of Tall Building” JGJ3-2010, screening seismic waves preliminarily based on designed seismic intensity, site category and seismic grouping of the building structure;
designing a normative spectrum of the building structure based on the “Code for Seismic Design of Buildings” GB50011-2010 and “Technical Specification for Concrete Structures of Tall Building” JGJ3-2010, and secondarily screening the seismic waves by taking, as a principle, the difference between spectrum values of an average response spectrum of a seismic motion response spectrum corresponding to principal mode period points of the building structure and spectrum values of the specification spectrum being not greater than 20%;
applying seismic waves filtered at the second time to the elastic-plastic calculation model of the building structure for elasticity time history analysis, and performing final seismic motion screening by taking, as a principle, a base shear force of the structure obtained by each seismic motion elasticity time history calculation being not less than 65% of a modal decomposition response spectrum method and an average value of the base shear force of the structure obtained by a plurality of seismic motion elasticity time history calculations being not less than 80% of the modal decomposition response spectrum method;
based on a final seismic motion screening principle, selecting main shock seismic motion records to obtain selected seismic waves;
step 3) performing main shock and main aftershock bidirectional excitation on the elastic-plastic calculation model of the building structure by using the selected seismic waves;
step 4) drawing an Incremental Dynamic Analysis (IDA) curve by taking a peak ground acceleration in the elastic-plastic calculation model subjected to bidirectional excitation as a seismic motion intensity measure, and selecting a maximum inter-story drift angle of a building structure system as a structural performance indicator;
step 5) performing non-uniform amplitude modulation on the seismic motion by using a Huntfill method, to search for collapse points of the building structure system;
based on the Huntfill method, drawing a family of IDA curves of the building structure under the selected seismic motion action;
drawing the IDA curves as percentile curves of 16%, 50% and 84% by using an Intensity Measure (IM) criterion in a statistical manner;
taking a 50% percentile curve as a reference, for different building structure systems, taking a value of an ultimate inter-story drift angle of the 50% percentile curve as an ultimate inter-story drift angle of a damage model, wherein the ultimate inter-story drift angle is a curve point, where the slope of a connecting line between a certain point and a point preceding the certain point is less than 20%, on an IDA curve, and taking the curve point as a maximum displacement point of structural collapse;
with regard to the plurality of selected seismic waves, based on a data result of multiple IDA curves, drawing a capacity curve of the building structure, and obtaining an average structural capacity curve, and calculating an area surrounded by the average structural capacity curve as an energy dissipation denominator E_{USE};
drawing an energy versus time history graph of the building structure under the action of the main shock and main after shock based on a seismic motion response time history of the structure, and obtaining a hysteretic energy dissipation E_{ΔE1} of a main shock and main after shock time history curve of the building structure, wherein the value of a strain energy increment E_{AEI} of the hysteretic energy dissipation is a ratio of the hysteretic energy dissipation E_{ΔE1} of the building structure to the seismic duration; and
step 6) based on a formula D_{SEN}=[(U_{rd}/U_{ud})^{1/2}]+ (E_{AEI}/E_{USE}), calculating a building structure overall damage index based on structural strain energy, and performing quantitative evaluation on the building structure overall damage;
wherein D_{SEN} is the building structure overall damage index; U_{rd} is a maximum response inter-story drift angle of the building structure under the seismic action; U_{ud} is a maximum ultimate inter-story drift angle of the building structure; E_{AEI} is a strain energy increment of the hysteretic energy dissipation; and E_{USE} is an ultimate strain energy of the building structure under the seismic action.

2. The method for quantitatively evaluating overall damage of building structure based on structural strain energy as claimed in claim 1, wherein in the step 1), an elastic-plastic analysis process comprises geometric nonlinearity, material nonlinearity, and construction process nonlinearity.

3. The method for quantitatively evaluating overall damage of building structure based on structural strain energy as claimed in claim 1, wherein the step 3) comprises:
performing main shock and main aftershock bidirectional excitation on the elastic-plastic calculation model of the building structure, to simulate a bidirectional seismic effect, wherein amplitude modulation of a proportionality coefficient is performed on each selected seismic motion, such that the amplitude-modulated seismic motion records cover seismic motions to which the structure may be subjected in various stages from an elastic stage, an elastic-plastic stage to a collapse stage.

4. The method for quantitatively evaluating overall damage of building structure based on structural strain energy as claimed in claim 1, wherein in the step 4), when the IDA curves are drawn, a data processing principle for the plurality of IDA curves is:
assuming that each (Displacement-Intensity Measure) DM-IM curve is subject to logarithmic distribution, and under a structural performance indicator value, obtaining an average value of different seismic motion intensity measure values and a standard deviation of different seismic motion intensity measure logarithmic values, and obtaining three percentile curves.

5. The method for quantitatively evaluating overall damage of building structure based on structural strain energy as claimed in claim 1, wherein the step 5) comprises:
determining end points of the IDA curves which represent ultimate collapse points of the building structure based on a structure collapse criterion.

6. The method for quantitatively evaluating overall damage of building structure based on structural strain energy as claimed in claim 1, wherein in the step (6), the building structure overall damage index is within a range of [0, 1]; when the building structure overall damage index is 0, it indicates that the building structure has no damage; and when the building structure overall damage index is 1, it indicates that the damage of the building structure is the greatest; and the larger the building structure overall damage index, the larger the damage degree of the building structure.
